(19) United States
(12) Patent Application Publication
(10) Pub. No.: US 2024/0077538 A1
(43) Pub. Date: Mar. 7, 2024

(54) Method and Device for Initially Preparing an Aging State Model for Energy Storage Means Based on Active Learning Algorithms and Time-Discounted Information Evaluation

(71) Applicant: Robert Bosch GmbH, Stuttgart (DE)

(72) Inventors: Christian Simonis, Leonberg (DE); Christoph Zimmer, Korntal (DE)

(21) Appl. No.: 18/454,282

(22) Filed: Aug. 23, 2023

(30) Foreign Application Priority Data
Aug. 29, 2022 (DE) 10 2022 208 930.8

(51) Int. Cl. G01R 31/367; G01R 31/36; G01R 31/382; G01R 31/392; G01R 31/396

(52) U.S. Cl. CPC G01R 31/367; G01R 31/3648; G01R 31/382; G01R 31/392; G01R 31/396

(57) ABSTRACT

A method for initially preparing an at least partially data-based aging state model for an electrical energy storage means is disclosed. The method includes providing a number of energy storage means on a test bench for measurement based on a respective load profile, wherein the load profiles are different and characterize a chronological trend of at least one load-imposing operational variable for the energy storage means. The method also includes operating the number of energy storage means having the respective associated load profile and recording chronological operational variable trends. Further, the method includes at a predetermined evaluation timepoint, determining an aging state of a subset of the energy storage means as a label based on an input vector, and generating a training data set, which includes the operational variable trends and the determined label, for each energy storage means of the subset of the energy storage means. The method additionally includes selecting the subset of the energy storage means having the respective associated load profile based on an information measure for the subset of the energy storage means, the measure being determined using a predictive covariance of the data-based aging state model at at least one future timepoint.

This application claims priority under 35 U.S.C. § 119 to patent application no. DE 10 2022 208 930.8, filed on Aug. 29, 2022 in Germany, the disclosure of which is incorporated herein by reference in its entirety.

The disclosure relates to methods and devices for initially preparing an at least partly data-based aging state model for electrical energy storage means of the same type, and in particular to methods for predicting the cost of measurement and/or the duration of measurement.

### BACKGROUND

The supply of energy for operating electrical devices and machines which are operated independently of energy networks, such as electrically-drivable motor vehicles, is generally done by electrical energy storage means such as device batteries or vehicle batteries.

Electrical energy storage means degrade over their lifetime depending on their load or usage. Referred to as aging, the result is a continuously decreasing maximum power or storage capacity. The aging state is a measure used to indicate the aging of energy storage means. By convention, a new device battery can have a 100% aging state (regarding its capacity, SOH-C) which decreases noticeably over the course of its service life.

One measure of aging of the energy storage means (change in the aging state over time) depends on an individual load on the energy storage means, i.e., in the case of vehicle batteries of motor vehicles the way a driver uses the vehicle, external ambient conditions and the type of vehicle battery.

In order to monitor aging states of electrical storage means in a plurality of devices, operational variable data can be continuously recorded and transferred in block fashion to a central processing unit external to the device as operational variable trends.

In order to use models to determine an aging state of an electrical energy storage means from operational variable data, it is necessary to provide a model of an initial aging state. To this end, an initial measurement, e.g. in a laboratory or on a test bench, is provided for a defined number of energy storage means, thereby generating training data for an aging state model to be provided. The energy storage means are operated differently for this purpose, it being necessary in particular to supply or dissipate energy in order to simulate operational cycles of the energy storage means, depending on the type of energy storage means. The energy expenditure required for this is significant and is scaled to the initial number of energy storage means being measured. The initial measurement can also take a considerable amount of time, in particular if sufficient training data remains to be recorded for aged energy storage means.

### SUMMARY

Provided according to the disclosure are a method for initially preparing an at least partly data-based aging state model for an electrical energy storage means, as well as a corresponding device. Further embodiments are specified in the description below.

According to a first aspect, a method is provided for initially preparing an at least partly data-based aging state model for an electrical energy storage means, comprising the following steps:
preparing a number of energy storage means on a measurement test bench, depending on a respective load profile, each load profile being different and characterizing a chronological trend of at least one load-imposing operational variable for the energy storage means;
operating the number of energy storage means having the respective load profile associated therewith and recording chronological operational variable trends;
at a predetermined evaluation timepoint, determining an aging state of a subset of the energy storage means as a label based on an input vector, and generating a training data set, which includes the operational variable trends and the determined label, for each energy storage means of the subset of energy storage means;
selecting the subset of energy storage means having the respective associated load profile based on an information measure for the subset of the energy storage means, the subset determined using a predictive covariance of the data-based aging state model at at least one future timepoint.

In particular, the subset of energy storage means selected based on the associated information measure can be the one for which a maximum information measure results. The information measure indicates the information gain that can be obtained, during ongoing measurement of the subset of energy storage means, for the aging state model trained using the resulting training data sets.

In device batteries acting as energy storage means, the aging state (state of health: SOH) is the key variable used to indicate a remaining battery capacity or remaining battery charge. The aging state represents a measure of the aging of the device battery. In the case of a device battery or a battery module or a battery cell, the aging state can be indicated as a capacity retention ratio (SOH-C). The capacity retention ratio SOH-C, i.e., the capacity-based aging state, is indicated as the ratio of the measured instantaneous capacity relative to an initial capacity of the fully-charged battery, and decreases with increased aging. Alternatively, the aging state can be indicated as an increase in internal resistance (SOH-R) relative to an internal resistance at the start of the service life of the device battery. The relative change in the internal resistance SOH-R increases with increasing aging of the battery.

The aging state of an electrical energy storage means is usually not measured directly. Doing so would require a number of sensors inside the energy storage means, which would make the production of such an energy storage means costly and complex, and would increase the space requirement. Moreover, measurement methods suitable for everyday use for direct determination of the aging state in the energy storage means are not yet available on the market.

Accurate methods for indirect, i.e., model-based determination of an aging state of energy storage means are computationally complex. Monitoring energy storage means of a plurality of devices is therefore performed in a central processing unit external to the device for reasons of capacity. For this purpose, the devices can transmit operational variable trends of operational variables of the device batteries to the central processing unit, in which case a current electrochemical state and/or aging state is determined in the central processing unit. Depending on the model used, time series of operational variables in the form of operational variable trends, e.g., a battery current, a battery temperature, a state of charge, and/or a battery voltage for a device battery acting as an energy storage means, are for this purpose recorded continuously or in time intervals, then transmitted in block fashion (and optionally in compressed form) to the central processing unit. The operational variable trends are evaluated in that location so that a device-specific aging state model, and optionally further variables, can be calculated or determined based on one or more aging state models. In addition, the operational variables from the plurality of energy storage means can be evaluated using statistical methods so that the applied aging state models can be improved, thereby noticeably improving the determination and prediction of the aging state of the energy storage means.

Due to the electrochemical effects in the operation of an energy storage means, which are often physically difficult to describe, the use of a data-based model as, or in connection with, a physical-based aging model has been proven effective as an aging state model.

A possible aging state model can be provided in the form of a hybrid aging state model, corresponding to a combination of a physical aging model with a data-based model. In a hybrid model, a physical aging state can be determined by means of a physical or electrochemical aging model, and a correction value resulting from a data-based correction model can be applied to said aging state, in particular by addition or multiplication. The physical aging model is based on electrochemical model equations that characterize electrochemical states of a non-linear differential equation system with regard to aging reactions, calculate them continuously in accordance with a chronological integration process, and map them onto the physical aging state for output, as SOH-C and/or as SOH-R. The calculations can typically be performed in the central processing unit (Cloud) at intervals of predetermined evaluation periods of, e.g., once a week.

Furthermore, the correction model of the hybrid data-based aging state model can be designed with a probabilistic or artificial intelligence-based probabilistic regression model, in particular a Gaussian process model, and can be trained to correct the aging state obtained by the physical aging model. A data-based correction model for correcting the capacity-based aging state and, optionally, a further data-based correction model for correcting the resistance-change-based aging state can be provided for this purpose. Possible alternatives to the Gaussian process include further supervised learning methods, such as those based on a random forest model, an AdaBoost model, a support vector machine, or a Bayesian neural network.

When commissioning a new type of energy storage means, it is necessary to be able to determine the aging state using an aging state model. Since, when commissioned, there is usually no precise knowledge of the aging behavior of the energy storage means, it is necessary to initially specify an aging state model which can indicate an aging state which is at least approximately based on operational variable trends provided. The initial setting of the aging state model thus requires an initial training of the data-based model.

Training data for such an initial training are usually determined in the laboratory or on a test bench and include a predetermined number of energy storage means, in particular randomly selected, each of which are operated under load profiles that are different from one another. These load profiles include cyclic current flows of individually-predetermined durations and trends, temperature profiles, and the like, or are converted into the same. In the case of device batteries in particular as energy storage means, these load profiles can comprise different charging and discharging current profiles at different temperatures, and in particular can be predetermined and characterized in a compressed manner by histogram data. These load profiles are implemented in time series of current inputs and current outputs, and corresponding operational variables, such as a battery current, a battery voltage, a battery temperature, and a state of charge, are recorded and stored as operational variable trends.

At predetermined timepoints, aging state measurements are taken using further suitable models or measurement methods to determine a label for the operational variable trends. Training data sets are created therefrom that can be used for parameterizing the aging state model and/or for training the data-based model in the case of a hybrid or purely data-based aging state model. Different aging state models and/or methods for label determination are considered.

A base model can be provided as a possible model or method for determining an aging state of a device battery as an energy storage means, an SOH-C measurement according to this model being made by coulomb counting or by generating a chronological current integral during the charging process, said measurement being divided by the charging state delta between the start and end of the respective charging and/or discharging phase. Advantageously, calibration against the idle voltage characteristic curve is performed in quiescent phases in order to co-calculate the charging state trend in the central processing unit. A sufficiently reliable indication of the aging state can, e.g., be obtained by bringing the vehicle battery from a fully-discharged charging state to a fully-charged state during a charging operation from a defined relaxed state under reproducible load and ambient conditions. The maximum charge recorded in this way can be related to an initial maximum charging capacity of the device battery. Resistance-based aging states (SOH-R values) can also be calculated by voltage changes relative to a current change. Typically, these changes are based on a defined time interval and defined ambient conditions and on the direction of energy flow of the system.

According to the above method, at predetermined timepoints, the aging states of a subset of the number of energy storage means can then be determined as a label, and a training data set which includes the operational variable trends and the determined label can be generated for each energy storage means of the subset of the energy storage means. The subset of the energy storage means having the respective associated load profile is selected based on the information measures for all of the energy storage means.

A method is therefore proposed in which the initially-provided aging state model is further trained at predetermined timepoints and only those energy storage means (a predetermined number J of selected energy storage means) that have a high contribution to the further development of the aging state model are measured at the predetermined timepoints. To this end, when using a probabilistic regression model as a data-based model for a respective timepoint t, the predictive covariance

Σ(SOHⱼ(t₁), SOHⱼ(t₂), . . . , SOHⱼ(tₙ))

of the data-based model resulting from the probabilistic regression model (Gaussian process model) provided in the aging state model SOHⱼ corresponds to aging states of a particular energy storage means j of the selected energy storage means at evaluation timepoints resulting from future evaluation timepoints t₁ . . . tₙ. The predictive covariance in Gaussian process models does not depend, as a probabilistic regression model, on previously unseen aging conditions, but only on the operational characteristics x̅(t)=[m(x(t)), z(x(t)), Phys[x(t)]) as input parameters of the Gaussian process model, and can therefore be written as

Σ(x̅ⱼ(t₁), x̅ⱼ(t₂), . . . , x̅ⱼ(tₙ))

where x(t) corresponds to one or more operational variable trends, m(t) corresponds to histogram data as a load profile, z(t) corresponds to multi-dimensional electrochemical states of the physical aging model, such as the SEI thickness, the amount of cyclizable lithium, the amount of active material, electrochemical concentrations and the like, and Phys[x(t)] correspond to the physical (modeled) aging state at a particular evaluation timepoint t. m(x(t)) as histogram data and z(x(t)) as electrochemical states represent operating features for the evaluation of the Gaussian process model at a particular evaluation timepoint t.

It can be provided that the amount of information is formed by a sum of predictive covariances at future, in particular successive evaluation timepoints at which training data sets for training the aging state model have been determined. In particular, the amount of information can be determined from the input vectors of the subset of a plurality of energy storage means for the evaluation timepoints of a total measurement period.

The total information measure for all selected energy storage means at an evaluation timepoint is given by:

$$h ( x ) = {\sum }_{t = t 1}^{T} h ( {\overline{x}}_{t} \vert {\overline{x}}_{1} , … , {\overline{x}}_{( t - 1 )} )$$

where x̅ₜ={x̅_{1.t}, . . . , x̅_{J,t}}, and J is the number of energy storage means selected. The predictive covariance Σ is a matrix to which information measures, such as the determinant or the maximum eigenvalue, can be applied.

Each entropy h(x̅ₜ|x̅₁, . . . , x̅₍ₜ₋₁₎) can be calculated as a predictive covariance

$$h ( {\overline{x}}_{t} \vert {\overline{x}}_{1} , … , {\overline{x}}_{( t - 1 )} ) = \frac{1}{2} {ln ( 2 π e )}^{d} det ( Σ ( {\overline{x}}_{t} \vert {\overline{x}}_{1} , … , {\overline{x}}_{( t - 1 )} )$$

such that the information measure for the entirety of the energy storage means is

$$h ( \overline{x} ) = {\sum }_{t = t}^{T} \frac{1}{2} {ln ( 2 π e )}^{d} det ( Σ ( {\overline{x}}_{t} \vert {\overline{x}}_{1} , … , {\overline{x}}_{( t - 1 )} )$$

where d corresponds to the dimension of the feature vector x̅ₜ.

The operational variable trends are always known in the laboratory and are deterministic. In reality, they can be predicted via load models, e.g. Hidden Markov models, especially currents and temperatures as timeseries signals. The load-imposed prediction of current dynamics, such as charging and discharging, can, e.g., be performed probabilistically, preferably using NARX Gaussian processes or Deep Bayesian networks. Then, using the load model, the load-free (parking) and load-imposed (charging/discharging) time-series signals are reassembled and assembled into time-series signal forecasts. The uncertainties in the load prediction can be propagated in the aging prediction. This is, e.g., performed using Monte Carlo methods in which:
sampling is performed based on a sufficiently high number of uncertainties in the charging prediction,
the prediction is made using the hybrid aging model, and/or
the confidence interval, which includes a point estimator and a battery state confidence, is associated with the sample.

The operational variable trends can be deterministically predetermined or can be probabilistically modeled.

Uncertainties in the prediction of operational variable trends from which the predictive operating features m(x(t)) and z(x(t)) are determined can be taken into account for each evaluation timepoint t by

\tilde{h}=∫h(x̅ₜ)(x̅ₜ)

where a probability distribution (\tilde{x}ₜ) of a load profile under which the associated energy storage means is operated applies for the evaluation timepoint t under consideration. This probability distribution, i.e., the probability of observing a feature x̅ₜ, can result from a probabilistic dynamic model and can be transferred to the information gain. Such a dynamic model generates artificial operational variable trends based on load profiles. The probability distribution indicates the probability that the generated operational variable trend corresponds to the actual operational variable trend.

According to one embodiment, the predictive covariances can each be weighted with a weighting factor prior to sum formation, the weighting factor weighting earlier predictive covariances higher than later ones.

In particular, the weighting factor can be determined as a power for a discounting factor using an index of a chronological step for ongoing evaluation timepoints.

In addition to the current planned load profiles, active learning can be used to generate further load profiles, in particular those that increase the information content. Doing so enables active learning to actively access load profiles in order to reach the best possible operating points for the energy storage means. The load profile results in operational variable trends having a corresponding probability distribution based on the probabilistic dynamic model.

In addition, discounting using a discounting factor γ<1 is taken into account, for deterministically predetermined operational variable trends x̅₁, . . . , x̅₍ₜ₋₁₎))

$${Info}_{J} = h ( \overline{x} ) = {\sum }_{t = t 1}^{T} {γ}^{k} \frac{1}{2} {ln ( 2 π e )}^{d} det ( Σ ( {\overline{x}}_{t} \vert {\overline{x}}_{1} , … , {\overline{x}}_{( t - 1 )} )$$

or for a probabilistic model for generating artificial operational variable trends

$${Info}_{J} = {\sum }_{c = C 1}^{T} {γ}^{k} \int \frac{1}{2} {ln ( 2 π e )}^{d} det ( Σ ( {\overline{x}}_{t} \vert {\overline{x}}_{1} , … , {\overline{x}}_{( t - 1 )} ) p L ( {\overline{x}}_{t} ) dx$$

where γ<1, k corresponds to the index of the respective chronological step for t₁ . . . T and d corresponds to the dimension of the operational variable vector x.

For this purpose, the operational variables must be predicted over a predetermined prediction horizon of 3 months, for example.

One reason in particular for the discounting is that the load prediction includes an uncertainty, for example if the load profiles and/or the operational variable trends are still being adjusted due to active learning or because the aging state model has not yet been sufficiently trained.

In the context of one variant of an active learning method, a number J (subset) of energy storage means B for which the respective information measure is a maximum can then be selected for measurement from the total quantity of the energy storage means Bₐₗₗ at the current evaluation timepoint.

B=argmax_{{B⊂B}_{ₐₗₗ}_{}}Info_{J}

The calculation can be performed using a Greedy method. First, the most informative battery is determined (the one having the highest information measure). Then, the battery supplementing this battery with the most information is determined (of the remaining batteries, the one having the highest information measure). Then the battery supplementing the selected batteries with the most information, etc.

For example, the number J of the energy storage means to be selected can be determined by comparing the reduction of the predictive variance in a validation data set. The decrease in the information measure Infoⱼ can then be related to the number of energy storage means, and a decision can be made, using a predetermined threshold, as to the amount of decrease that can be accepted for measurement of an energy storage means to continue.

According to the method, specific measurements of the aging state are then taken for the selected energy storage means and are not taken for the non-selected energy storage means. In other words, if sufficient new information is available, re-training of the data-based aging state model will take place. Together with the associated operational variable trends, this results in a training data set to further improve on the initial aging state model.

Training can be supplemented by automated hyperparameter tuning, for example via gradient-based methods or blackbox methods, such as Bayesian optimization.

The method described above can be ended when the results fall below a certain accuracy requirement, e.g. <1.5 SOHC, in a relevant, previously provided validation data set, and if various robustness requirements, for example those evaluated via cross-validation, are met.

It can be provided that at each evaluation timepoint, only the energy storage means of the subset of the energy storage means are measured as a label to determine an aging state, and the remaining energy storage means continue to be operated in accordance with the load profile.

Furthermore, the data-based aging state model can be designed to include a probabilistic data-based model, in particular a Gaussian process model, whereby for one of the energy storage means, an input vector of the data-based model can be mapped onto the aging state to be modeled of the relevant energy storage means or onto a correction variable for correcting a physically-modeled aging state of the relevant energy storage means, the input vector including at least one operational variable trend and/or at least one operating feature from the at least one operational variable trend, an internal state of the energy storage means and/or a physically-modeled aging state, in which case the information measure for the subset of the energy storage means is determined using a determinant of the predictive covariance for the respective energy storage means.

Furthermore, at each evaluation timepoint, only the energy storage means of the subset of the energy storage means can be measured as a label to determine an aging state, and the remaining energy storage means continue to be operated according to the associated load profile.

Alternatively, at each evaluation timepoint, only the energy storage means of the subset of the energy storage means can be measured as a label to determine an aging state and further operated according to the load profile, while the remaining energy storage means are removed from the test bench.

It can be provided that the aging state model is trained using the determined training data sets.

According to a further aspect, a device is provided for performing one of the above methods.

### BRIEF DESCRIPTION OF THE DRAWINGS

Embodiments are explained in greater detail hereinafter with reference to the accompanying drawings. Shown are:

FIG. 1 a schematic representation of a test bench for measuring a plurality of vehicle batteries for creating an initial aging state model;

FIG. 2 a schematic representation of a hybrid aging state model;

FIG. 3 a flowchart for illustrating a method for optimized creation of an initial aging state model;

FIG. 4 a representation of an aging trend involving a decrease in battery capacities of different vehicle batteries under different load patterns.

### DETAILED DESCRIPTION

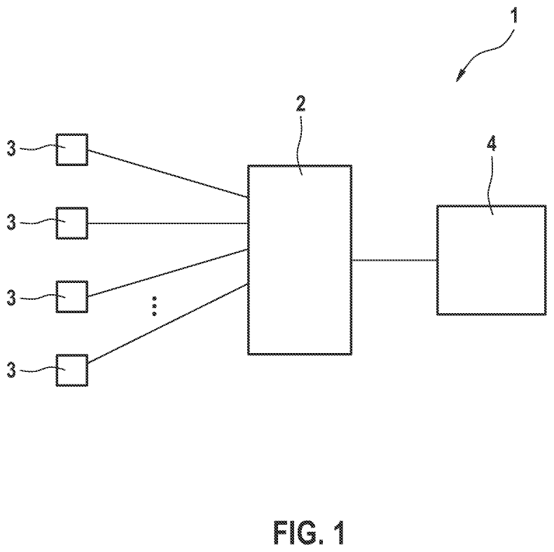

FIG. 1 shows a schematic arrangement of a test bench, comprising a test bench unit 2 connected to a plurality of connected vehicle batteries 3 as electrical energy storage means. The test bench unit 2 controls the vehicle batteries 3 according to a predetermined load pattern that characterizes various current trends and/or temperature trends. The current trends and/or temperature trends cause different loads and are thus different cyclic agings of the vehicle batteries 3, for example by specifying an ampere-hour throughput, specifications for charging profiles, in particular maximum charging currents depending on the charging state when charging, maximum charging currents when discharging, maximum and average charging and discharging currents, and corresponding temperature conditions. The load patterns are predetermined for each of the vehicle batteries 3 and correspond to more or less load-imposing modes of operation of the vehicle batteries 3. Chronological operational variable trends of the vehicle batteries 3 are continuously recorded and temporarily stored. The operational variable trends include, for vehicle batteries, a battery voltage, a battery current, a battery temperature, and a state of charge.

The test bench 1 serves to record data on the aging of the vehicle batteries 3 in order to prepare a corresponding initial aging state model 4 which enables the determination of the current aging state of the vehicle battery in question at a predetermined minimum accuracy based on operational variable trends recorded during operation in real-time. The aging state model 4 to be created for this purpose can be at least partially data-based and can include a data-based probabilistic regression model.

The measurement of the plurality of device batteries 3 on the test bench 1 enables the aging state to be determined for selected vehicle batteries 3 at regular timepoints using a suitable method. In connection with the corresponding associated operational variable trends predetermined by the respective load patterns associated with the vehicle battery 3 in question, this results in training data sets which can be used to train the data-based/hybrid aging state model 4. The use of the test bench 1 and the measurement of the plurality of vehicle batteries 3 incurs costs due, on the one hand, to the energy expenditure, and on the other hand to the run time of the test bench, and the use of various other materials. These costs are to be reduced when measuring the plurality of vehicle batteries 3 without compromising the quality of the initial trained aging state model 4.

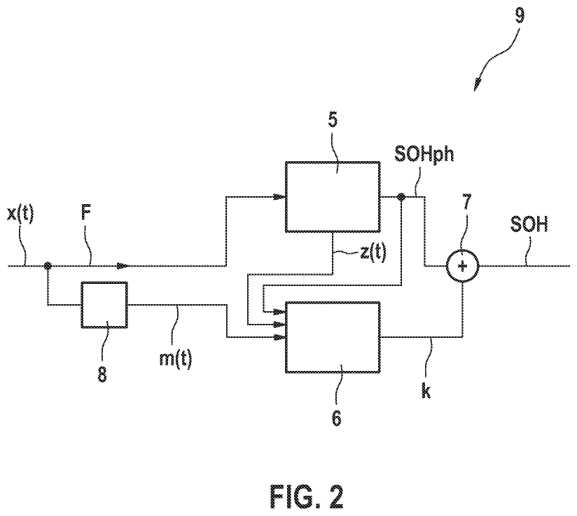

FIG. 2 schematically shows, by way of example, the functional structure of an embodiment of a data-based aging state model 9 conceived in a hybrid manner. The aging state model 9 comprises a physical aging model 5 and a data-based correction model 6.

The physical aging model 5 is a non-linear mathematical model based on differential equations. The evaluation of the physical aging model 5 of the aging state model 9 using operational variable trends, in particular since the start of the service life of the vehicle battery, results in an internal state of the equation system of the physical differential equations being established which corresponds to a physical internal state of the vehicle battery. Since the physical aging model is based on physical and electrochemical principles, the model parameters of the physical aging model are variables that indicate physical properties.

The time series of the operational variables x(t) of the vehicle battery to be evaluated thus enter directly into the physical aging state model 5, which is preferably designed as an electrochemical model and describes corresponding internal electrochemical states z(t), such as layer thicknesses (e.g., SEI thickness), change in cyclable lithium due to anode/cathode side reactions, rapid consumption of electrolytes, slow consumption of electrolytes, loss of active material in the anode, loss of active material in the cathode, etc., by means of non-linear differential equations in a multi-dimensional state vector.

The physical aging model 5 thus corresponds to an electrochemical model of the respective vehicle battery 3. This model determines, depending on the operational variable trends x(t), internal physical battery states z(t) in order to provide a physically-based aging state SOHph=Phys[x(t)] of at least first order, as a function of the electrochemical states z(t) mentioned above, the states being mapped linearly or non-linearly onto a capacity retention ratio (SOH-C) and/or an internal resistance increase ratio (SOH-R) in order to make this available later as an aging state (SOH-C and SOH-R).

However, the model values for the physical aging state SOHph provided by the electrochemical model are inaccurate in certain situations and it is therefore provided to correct them with a correction variable k. The correction variable k is provided by the data-based correction model 6, which is trained using training data sets determined by the test bench 1.

Preferably, the data-based correction model corresponds to a Gaussian process modelGP=GP[m(x(t)), z(x(t)), Phys[x(t)]))˜ [symbol] (μ,Σ), where μ is an m×1-dimensional vector which indicates the predictive mean at an evaluation timepoint t and Σ is the m×m-dimensional predictive covariance matrix of the Gaussian process model. The formulas for the mean and the variance of the Gaussian process are as follows:

μ(x̅)=k^{T}C_{N}⁻¹y

ρ(x̅)=c−k^{T}C_{N}⁻¹k

where N corresponds to the number of labels, x̅ is m×d-dimensional and indicates an amount m of new points in the input space, where x̅=[m(x(t)), z(x(t)), Phys[x(t)]) and y each correspond to an N×1-dimensional vector, and where y indicates a measured aging state or an aging state determined as a label, respectively. k corresponds to an N×m-dimensional matrix of kernel evaluations indicating correlations between the m new points and the N measured points encoded in the kernel of the Gaussian process. C corresponds to an N×N-dimensional matrix of kernel evaluations between the N measured points and c corresponds to an m×m matrix with kernel evaluations between the m new points. T denotes the transpose matrix. See also Bishop, “Pattern Recognition and Machine Learning”, 2006.

On the input side, the correction model 6 receives operating features m(x(t)) which can be determined from the predicted or predetermined trends of the operational variables x(t₀ . . . tₙ) for future evaluation timepoints and can also include one or more of the internal electrochemical states of the differential equation system of the physical model 5. Furthermore, the correction model 6 can receive on the input side the physical aging state SOHph obtained from the physical aging model 5. The operating features m(t) of the current evaluation timepoint t are generated in a feature extraction block 8 based on the operational variable trends x(t0 . . . t). Furthermore, the internal states z(x(t)) from the state vector of the electrochemical physical aging model 5 and, advantageously, the physical aging state SOHph are fed to the correction model 6. The feature vector m(x(t)) is robust because it is independent of the model quality of the physical aging model or its state. Therefore, taking the feature vector m(x(t)) into account is a sensible addition to the internal states z(x(t)) of the physical or electrochemical aging model.

From the predicted or predetermined operational variable trends x(t₀ . . . tₙ), operating features m(x(t)) relating to an evaluation period can also be generated in the central processing unit 2 for each vehicle fleet 3 or, in other embodiments, even already in the respective motor vehicles. The evaluation period between two evaluation timepoints can be a few hours (e.g., 6 hours) to several weeks (e.g., one month) for determining the aging state. A typical value for the evaluation period is one week.

The operating features m(x(t)) can, for example, include features relating to the evaluation period and/or accumulated features and/or statistical variables determined over the entire previous service life. In particular, the operating features can include, for example: electrochemical states, such as SEI layer thickness, change of cyclable lithium due to anode/cathode side reactions, rapid absorption of electrolyte solvents, slow absorption of electrolyte solvents, lithium deposition, loss of active anode material and loss of active cathode material, information on impedances or the internal resistances, histogram features, such as temperature over state of charge, charging current over temperature and discharging current over temperature, in particular multi-dimensional histogram data with respect to the battery temperature distribution over the state of charge, the charging current distribution over the temperature and/or the discharging current distribution over the temperature, the current flow rate in ampere-hours, the accumulated total charge (Ah), an average increase in capacity during a charging operation (in particular for charging operations in which the charge increase is above a threshold fraction [e.g., 20% ΔSOC] of the total battery capacity), the charging capacity as well as an extreme value (e.g., maximum) of the differential capacity during a measured charging operation with sufficiently large delta of the state of charge (smoothed trend of dQ/dU: charge change divided by change in the battery voltage) or the accumulated driving power. These values are preferably converted such that they optimally characterize the real-world usage behavior and are standardized in the feature space. The operating features m(t) can be used altogether or only in part for the method described below.

For the determination of a corrected aging state SOH to be output, the outputs SOHph, k of the physical aging model 5 and of the data-based correction model 6, which is preferably designed as a Gaussian process model, are applied together. In particular, they can be added or otherwise also multiplied (not shown) in a summing block 7 in order to obtain the modeled aging state SOH to be output for a current evaluation period. The confidence of the Gaussian process can still be used in the addition case as the confidence of the corrected aging value SOH of the hybrid model to be output. The confidence or the confidence value of the Gaussian process model thus characterizes the modeling uncertainty of mapping operational feature points onto an aging state.

The initial training of the hybrid aging state model 9 is performed in the test bench 1. For this purpose, training data sets are established which assign operational variable trends of a vehicle battery operated based on a load profile to an empirically-determined or model-based-determined aging state as a label. The goal is for the hybrid aging state model to accurately predict the non-linear, sudden decrease in capacity. This can be achieved via the combination of electrochemically-modeled cause-effect chains as well as machine learning.

For example, to determine an aging state as a label for training the hybrid or data-based aging state model, a base model can be provided according to which SOH-C measurement is measured by coulomb counting or by generating a chronological current integral during the charging process under defined ambient conditions, the base model being divided by the delta of the charge state between the beginning and the end of the respective charging and/or discharging phase. A sufficiently reliable indication of the state of aging can be obtained, for example, if the vehicle battery is brought from a fully discharged charging state to a fully charged state out of a defined relaxed state during a charging operation under reproducible load and ambient conditions. The maximum charge recorded this way can be related to an initial maximum charging capacity of the vehicle battery. Resistive aging states (SOH-R values) can also be calculated by voltage changes relative to a current change. Typically, these changes are based on a defined time interval and defined ambient conditions and on the direction of energy flow of the system.

Determination of an aging state as a label can be done in a known manner by evaluating the operational variable trends using an additional aging model under defined load and ambient conditions of a label generation, such as constant temperature, constant current, and the like. Other models can be used to determine the aging state as well. Training of the data-based correction model can be performed in a conventional manner based on the training data sets and the residues of the modelled aging state.

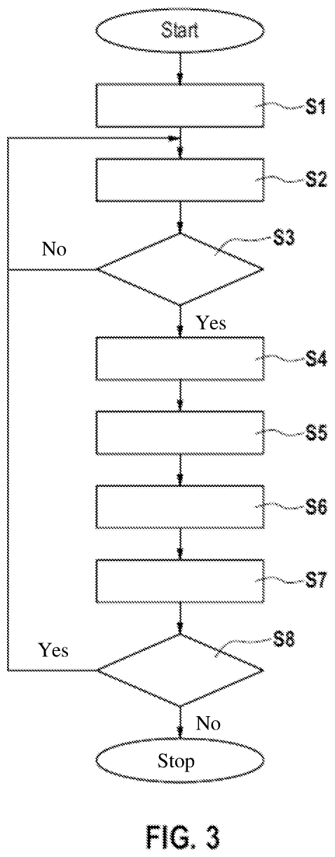

FIG. 3 shows a flowchart describing the process of performing the measurement of the plurality of vehicle batteries 3 on the test bench 1. The method is performed in test bench control unit 2 and results in the preparation of an initial data-based aging state model 4 that enables sufficient accuracy in determining the aging state based on operational variable trends of vehicle batteries 3 in real-world operations.

In step S1, the test bench 1 is equipped with a plurality of factory-new vehicle batteries 3 (or those in a reference state) of the same type, and each of the vehicle batteries 3 is assigned a predetermined load pattern. The load patterns are different, each representing a load which is in the range of low to high loading for the associated vehicle battery 3. The load patterns provide information from which chronological trends of a battery current can be derived in connection with temperature trends that stress the vehicle batteries 3 in different ways. These load patterns can also directly pre-determine the operational variable trends. Alternatively, the operational variable trends can also be predetermined using a predetermined probabilistic model based on the load patterns. The load patterns are then predictive in nature and represent a prediction into the future. Advantageously, in addition to a point estimator, especially for temperature and current, they also include a confidence.

In step S2, the plurality of vehicle batteries 3 are operated according to the predetermined load pattern.

In step S3, it is checked whether an evaluation timepoint t has been reached. The evaluation timepoint can be provided at regular intervals, for example at intervals of between one week and two months.

If an evaluation timepoint is reached (alternative: Yes), then the method is continued with step S4; otherwise, a return to step S2 is made.

Starting from the previous training state of the aging state model, an information measure Info_{J} is then determined in step S4 for a subset of the vehicle batteries 3, said measure indicating the information gain that can be obtained by further measuring the subset of the vehicle batteries 3. This information measure can be indicated using a predictive covariance of the data-based aging state model. In particular, when using a Gaussian process model as a probabilistic regression model as part of the aging state model, the predictive covariance of an energy storage means (Index j)

Σ(SOHⱼ(t₁), SOHⱼ(t₂), . . . , SOHⱼ(tₙ))

is not dependent on aging conditions that have not yet been determined, but only on input variables x(t₀ . . . tₙ) at the current timepoint for t₀ and at future timepoints or chronological steps for t₁ . . . tₙ. As described above, there is an information measure for a subset B of the total number of vehicle batteries Bₐₗₗ given as

$${Info}_{J} = h ( \overline{x} ) = {\sum }_{t = t 1}^{T} {γ}^{k} \frac{1}{2} {ln ( 2 π e )}^{d} det ( Σ ( {\overline{x}}_{t} \vert {\overline{x}}_{1} , … , {\overline{x}}_{( t - 1 )} )$$

where x̅ₜ={x̅_{1.t}, . . . , x̅_{J,t}} represents the operating characteristics derived from the operational variable trends for an evaluation timepoint t for all vehicle batteries considered (index 1 . . . J). γ<1, and corresponds to a discounting factor which decreases over the chronological steps k (increasing k).

In conclusion, in step S4, the information measure is obtained which relates to the expected information gain from a measurement of a subset of vehicle batteries 3 from the entirety of the vehicle batteries 3. The evaluated information measures refer to the future, but are evaluated via discounting with regard to chronological relevance, and take into account uncertainties already propagated with regard to a load and aging prediction.

In a step S5, information measures for subsets B of vehicle batteries, each subset having a predetermined number J of vehicle batteries, are then calculated and the subset B of the vehicle batteries having a maximum information measure is selected.

B=argmax_{{B⊂B}_{ₐₗₗ}_{}}Info_{J}

In step S6, the vehicle batteries 3 of the selected subset are then measured and in step S7, a label in the form of a measured aging state is determined at the current evaluation timepoint.

An active learning process is performed thereby. The goal of active learning is to reduce test bench duration, and thus costs, without compromising model accuracy. This can be achieved by actively intervening in the operational variable trend via active learning in a closed control loop, e.g. by adjusting the current or temperature at the test bench in order to generate a relevant state in at least one battery.

Subsequently, in step S6, the selected vehicle batteries 3 are used to take a highly accurate measurement of the aging state, as a label, under reproducible, defined conditions (temperature, charging/or discharging direction, current, ambient conditions, etc.).

The determination of the aging state can be performed using a suitable aging state model or a suitable measurement method for determining the aging state.

As a possible model or method for determining an aging state, a coulomb counting measurement can be used, or by generating a chronological current integral during the charging process. In this case, the transferred charge is divided by the delta of the state of charge between the start and the end of the respective charging and/or unloading phase. Advantageously, calibration against the idle voltage characteristic curve is performed in quiescent phases in order to co-calculate the state of charge trend in the central processing unit. A sufficiently reliable indication of the state of aging can be obtained, for example, when the vehicle battery is brought from a fully discharged charging state to a fully charged state out of a defined relaxed state during a charging operation under reproducible load and ambient conditions. The maximum charge recorded as a result can be related to an initial maximum charging capacity of the vehicle battery 3.

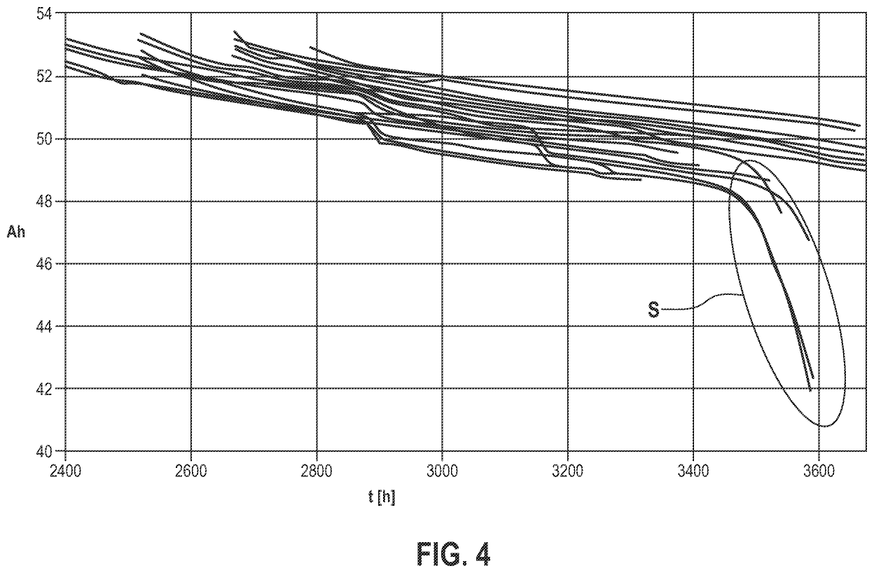

For the plurality of vehicle batteries 3, trends of the aging states result, as shown in FIG. 4 for example. It can be seen that there is a sudden death event S. The sooner such information can be measured and incorporated into the modeling through training, the faster the training can occur. The goal here is for the aging model to be able to very accurately predict the non-linear, sudden decrease.

In connection with operational variable trends resulting from the load pattern and the determined aging state as a label, training data sets are available with which the aging state model 4 can be trained. The training data sets thus newly determined are used in step S7 for further training of the data-based probabilistic regression model. In addition, an automated hyperparameter tuning, e.g., via gradient-based methods or blackbox methods, such as Bayesian optimization, can be performed.

In a subsequent step S8, it is checked whether the trained aging state model for a provided validation data set exceeds a sufficient accuracy of, e.g., a maximum error of 1.5% SOHC. If so, (alternative: yes), the method is continued at step S2, otherwise (alternative: no) the measurement of the vehicle batteries 3 is ended.

What is claimed is:

1. A method for initially preparing an at least partly data-based aging state model for an electrical energy storage means, comprising:
providing a number of energy storage means on a test bench for measurement depending on a respective load profile, wherein the load profiles are different and characterize a chronological trend of at least one load-imposing operational variable for the energy storage means;
operating the number of energy storage means having the respective associated load profile and recording chronological operational variable trends;
at a predetermined evaluation timepoint, respectively determining an aging state of a subset of the energy storage means as a label based on an input vector, and generating a training data set which includes the operational variable trends and the determined label for each energy storage means of the subset of the energy storage means; and
selecting the subset of energy storage means having the respective associated load profile based on an information measure for the subset of the energy storage means, the measure being determined using a predictive covariance of the data-based aging state model at at least one future timepoint.

2. The method according to claim 1, wherein the information measure is generated using a sum of predictive covariances at future evaluation timepoints at which training data sets for training the aging state model have been determined.

3. The method according to claim 2, wherein the information measure is determined from the input vectors of the subset of the plurality of energy storage means for the evaluation timepoints of a total measurement period.

4. The method according to claim 2, wherein the predictive covariances are each weighted with a weighting factor prior to summing, the weighting factor weighting predictive covariances in the near future higher than those further out.

5. The method according to claim 4, wherein the weighting factor is determined as the power for a discounting factor using an index of a chronological step for ongoing evaluation timepoints.

6. The method according to claim 2, wherein:
in the case of unknown operational variable trends of one or more of the energy storage means, an artificial operational variable trend is generated and the predictive covariances are each multiplied by a probability distribution of a probability that the artificial operational variable trend corresponds to the actual operational variable trend.

7. The method according to claim 1, wherein:
the data-based aging state model is designed to include a probabilistic data-based model,
for one of the energy storage means, an input vector of the data-based model can be mapped onto the aging state to be modeled of the relevant energy storage means or onto a correction variable for correcting a physically-modeled aging state of the relevant energy storage means, the input vector including at least one operational variable trend and/or at least one operating feature from the at least one operational variable trend, an internal state of the energy storage means and/or a physically-modeled aging state, and
the information measure for the subset of the energy storage means is determined using a determinant of the predictive covariance for the respective energy storage means.

8. The method according to claim 1, wherein at each evaluation timepoint, only the energy storage means of the subset of the energy storage means for determining an aging state are measured as a label, and the remaining energy storage means are operated according to the associated load profile.

9. The method according to claim 1, wherein at each evaluation timepoint, only the energy storage means of the subset of the energy storage means for determining an aging state are measured as a label and further operated according to the load profile, while the remaining energy storage means are removed from the test bench.

10. The method according to claim 1, wherein by means of active learning the load profile and/or the resulting operational variable trend is adjusted for the further measurement of one or more of the energy storage means.

11. The method according to claim 1, wherein the aging state model is trained using the determined training data sets.

12. The method according to claim 1, wherein the subset of energy storage means selected based on the associated information measure is the one for which a maximum information measure results.

13. A device for performing the method according to claim 1.

14. A computer program comprising instructions that, when the program is executed by at least one data processing device, prompt the latter to perform the method steps according to claim 1.

15. A machine-readable storage medium which includes instructions that, when executed by at least one data processing device, prompt the latter to perform the steps of the method according to claim 1.

16. The method according to claim 1, wherein the information measure is generated using a sum of predictive covariances at future, successive evaluation timepoints at which training data sets for training the aging state model have been determined.

17. The method according to claim 1, wherein:
the data-based aging state model is designed to include a Gaussian process model,
for one of the energy storage means, an input vector of the data-based model can be mapped onto the aging state to be modeled of the relevant energy storage means or onto a correction variable for correcting a physically-modeled aging state of the relevant energy storage means, the input vector including at least one operational variable trend and/or at least one operating feature from the at least one operational variable trend, an internal state of the energy storage means and/or a physically-modeled aging state, and
the information measure for the subset of the energy storage means is determined using a determinant of the predictive covariance for the respective energy storage means.
